(19) United States
(12) Patent Application Publication
(10) Pub. No.: US 2025/0359471 A1
(43) Pub. Date: Nov. 20, 2025

(54) DISPLAY DEVICE

(71) Applicant: Samsung Display Co., LTD., Yongin-si (KR)

(72) Inventors: Bo Kwang SONG, Yongin-si (KR); Hyoeng Ki KIM, Yongin-si (KR); Chaun Gi CHOI, Yongin-si (KR); Gee Bum KIM, Yongin-si (KR); Hyeon Bum LEE, Yongin-si (KR)

(21) Appl. No.: 19/192,698

(22) Filed: Apr. 29, 2025

(30) Foreign Application Priority Data
May 16, 2024 (KR) 10-2024-0063587

(51) Int. Cl. H10K 59/80; H10K 59/122; H10K 59/123

(52) U.S. Cl. CPC H10K 59/8792; H10K 59/122; H10K 59/123; H10K 59/80515

(57) ABSTRACT

A display device includes a substrate, a via layer disposed on the substrate and having an inclined structure, a first electrode disposed on the inclined structure, where the first electrode includes an inclined portion and an extension portion, a pixel defining layer disposed on the via layer and an inclined portion of the first electrode, where an opening exposing an extension of the first electrode is defined through the pixel defining layer, an organic light emitting layer disposed on the first electrode and a second electrode disposed on the organic light emitting layer, where the extension portion extends from a top end of the inclined portion, the inclined portion corresponds to an edge portion of the first electrode, and a bottom end of the inclined portion is closer to the substrate than the top end thereof is.

This application claims priority to Korean Patent Application No. 10-2024-0063587, filed on May 16, 2024, and all the benefits accruing therefrom under 35 U.S.C. § 119, the content of which in its entirety is herein incorporated by reference.

### BACKGROUND

### 1. Field

Embodiments of the disclosure relate to a display device.

### 2. Description of the Related Art

In general, a flat panel display device, such as a liquid crystal display device or an organic light emitting display device, includes a plurality of pairs of electric field generating electrodes and an electro-optical active layer between a corresponding pair of electronic field generating electrodes. The liquid crystal display device includes a liquid crystal layer as an electro-optical active layer, and an organic light emitting display device includes an organic light emitting layer as an electro-optical active layer.

In general, organic light emitting display devices are capable of realizing color on the principle that holes and electrons injected from the anode and cathode recombine in the light emitting part to emit light and have a stacked structure in which a light emitting layer is inserted between the pixel electrode, which is the anode, and the counter electrode, which is the cathode.

Organic light emitting display devices are attracting attention as next generation display devices because such organic light emitting display devices may exhibit high-quality characteristics such as low power consumption, high brightness, and high response speed.

### SUMMARY

Embodiments of the disclosure provide a display device that may reduce external light reflectance without reducing the light output efficiency of the display device.

However, embodiments of the disclosure are not restricted to the one set forth herein. The above and other features of embodiments of the disclosure will become more apparent to one of ordinary skill in the art to which the disclosure pertains by referencing the detailed description of the disclosure given below.

According to an embodiment, a display device includes a substrate, a via layer disposed on the substrate and having an inclined structure, a first electrode disposed on the inclined structure, where the first electrode includes an inclined portion and an extension portion, a pixel defining layer disposed on the via layer and an inclined portion of the first electrode, where an opening exposing an extension of the first electrode is defined through the pixel defining layer, an organic light emitting layer disposed on the first electrode and a second electrode disposed on the organic light emitting layer, where the extension portion extends from a top end of the inclined portion, the inclined portion corresponds to an edge portion of the first electrode, and a bottom end of the inclined portion is closer to the substrate than the top end thereof is.

In an embodiment, the inclined portion may have a surface forming a first inclination angle with respect to a plane parallel to the substrate, and the first inclination angle may be in a range of about 10° to about 30°.

In an embodiment, the inclined structure may include a first portion having a surface forming a second inclination angle with respect to a plane parallel to the substrate, and a second portion extending from a top end of the first portion.

In an embodiment, the second inclination angle may be in a range of about 10° to about 30°.

In an embodiment, the inclined portion may overlap the first portion in a plan view, and the extension portion may overlap the second portion in the plan view.

In an embodiment, an upper width of the inclined structure may be less than a lower width thereof.

In an embodiment, the via layer may include a first via layer disposed in an island-shape in an area overlapping the opening, and a second via layer covering the first via layer and disposed on an entire surface of the substrate.

In an embodiment, the pixel defining layer may include a transparent organic material, where the pixel defining layer may have a lower refractive index than the via layer.

In an embodiment, the pixel defining layer may include a first pixel defining layer including a black component, and a second pixel defining layer disposed on the first pixel defining layer, where the second pixel defining layer may include a transparent organic material and have a lower refractive index than the first pixel defining layer.

In an embodiment, the first pixel defining layer may define the opening, where the second pixel defining layer may not be in contact with the organic light emitting layer.

In an embodiment, the black component may include at least one material selected from carbon black, chromium, and chromium oxide.

In an embodiment, the via layer may include at least one material selected from carbon black, chromium, and chromium oxide.

In an embodiment, the inclined portion may overlap the first portion and expose at least a portion of the first portion.

In an embodiment, the display device may further include a thin film transistor disposed between the substrate and the via layer and a planarization layer disposed between the thin film transistor and the via layer, where the first electrode may be electrically connected to the thin film transistor.

According to an embodiment, a display device includes a substrate, a via layer disposed on the substrate and having an inclined structure, a first electrode disposed on the inclined structure, where the first electrode includes an inclined portion and an extension portion, a pixel defining layer disposed on the via layer and an inclined portion of the first electrode, where an opening exposing an extension of the first electrode is defined through the pixel defining layer, an organic light emitting layer disposed on the first electrode, a second electrode disposed on the organic light emitting layer, an encapsulation layer disposed on the second electrode and a light blocking pattern disposed on the encapsulation layer, where a surface of the inclined portion has a first inclination angle with respect to a plane parallel to the substrate, and the first inclination angle is at least half of a third inclination angle formed between an imaginary line extending from one end of the pixel defining layer to one end of a light blocking pattern adjacent to the one end of the pixel defining layer and an imaginary vertical line of the substrate.

In an embodiment, the extension portion may extend from a top of the inclined portion, where the inclined portion may correspond to an edge portion of the first electrode, and a bottom end of the inclined portion may be closer to the substrate than the top end thereof is.

In an embodiment, the light blocking pattern may include at least one material selected from carbon black, chromium, and chromium oxide.

In an embodiment, the first inclination angle may be in a range of about 10° to about 30°.

In an embodiment, the via layer may include a first via layer disposed in an island-shape in an area overlapping the opening, and a second via layer covering the first via layer and disposed on the entire surface of the substrate.

In an embodiment, the display device may further include a thin film transistor disposed between the substrate and the via layer and a planarization layer disposed between the thin film transistor and the via layer, where the first electrode may be electrically connected to the thin film transistor.

According to embodiments of the disclosure, a display device with increased light output efficiency and reduced external light reflectance may be implemented.

### BRIEF DESCRIPTION OF THE DRAWINGS

FIG. 1 is a perspective view of a display device according to an embodiment.

FIG. 2 is a plan view of a display device according to an embodiment.

FIG. 3 is a cross-sectional view illustrating a portion of a cross-section taken along line I-I′ of FIG. 2.

FIG. 4 is a cross-sectional view illustrating an example of a structure of a sub-pixel included in a display device according to an embodiment of the disclosure.

FIGS. 5 and 6 are enlarged views of area A of FIG. 4.

FIG. 7 is a graph illustrating the relationship between the reflectance and the tilt angle and the thickness of the through layer and the tilt angle according to an embodiment.

FIG. 8 is a cross-sectional view illustrating an example of a structure of a sub-pixel included in a display device according to an embodiment of the disclosure.

FIG. 9 is an enlarged view of area B of FIG. 8.

FIG. 10 is a cross-sectional view illustrating an example of a structure of a sub-pixel included in a display device according to an embodiment of the disclosure.

FIG. 11 is an enlarged view of area C of FIG. 10.

FIGS. 12 to 14 are cross-sectional view illustrating a structure of a sub-pixel corresponding to FIG. 5, according to other embodiments.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

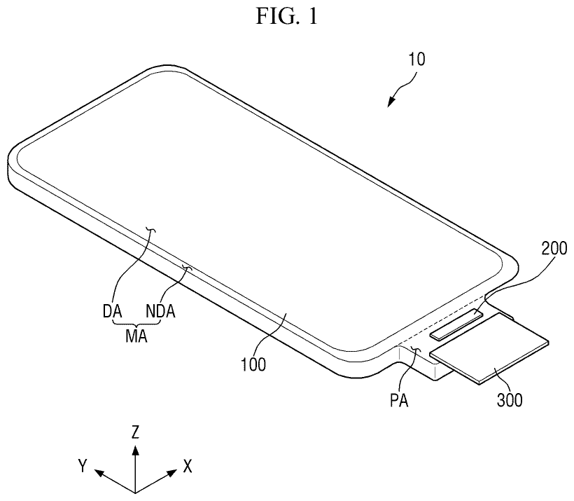

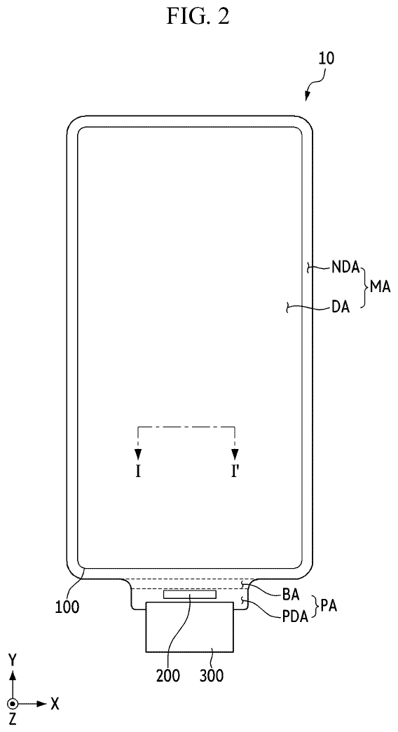

FIG. 1 is a perspective view of a display device according to an embodiment. FIG. 2 is a plan view of a display device according to an embodiment.

Referring to FIGS. 1 and 2, an embodiment of the display device 10 is a device for displaying video or still images, such as a mobile phone, smart phone, tablet personal computer (TPC), and portable electronic devices, for example, a smart watch, watch phone, mobile communication terminal, electronic notebook, laptop computers, e-books, portable multimedia players (PMP), navigation systems, ultra mobile PC (UMPC), and the like, as well as electronic devices such as televisions, monitors, billboards, internet of things (IoT), and other products. The display device 10 may be an organic light emitting display device, a liquid crystal display device, a plasma display device, a field emission display device, an electrophoretic display device, an electrowetting display device, a quantum dot light emitting display device, or a micro-LED display device. Hereinafter, for convenience of description, embodiments where the display device 10 is an organic light emitting display device will be mainly described, but the disclosure is not limited thereto.

The display device 10 according to an embodiment includes a display panel 100, a display driving circuit 200, and a circuit board 300.

The display panel 100 may include a main area MA and a protruding area PA protruding or extending from one side of the main area MA.

The main area MA may be formed as a rectangular plane (or have a rectangular planar shape) having a short side in a first direction (X-axis direction) and a long side in a second direction (Y-axis direction) that intersects the first direction (X-axis direction). Here, a third direction (Z-axis direction) may be a direction perpendicular to the first and second directions or may be a thickness direction of the display panel 100. A corner where the short side in the first direction (X-axis direction) and the long side in the second direction (Y-axis direction) meet may be rounded to have a predetermined curvature or may be formed at a right angle. The planar shape of the display device 10 is not limited to a square shape, and may be formed in other polygonal, circular, or oval shapes. The main area MA may be formed flat, but not be limited thereto. In another embodiment, the main area MA may include curved portions formed at left and right ends. In such an embodiment, the curved portion may have a constant curvature or a varying curvature.

The main area MA may include a display area DA, in which pixels are provided or formed to display an image, and a non-display area NDA that is a peripheral area of the display area DA.

In the display area DA, not only pixels but also scan lines, data lines, and power supply lines connected to the pixels may be disposed. In an embodiment where the main area MA includes a curved portion, the display area DA may be disposed on the curved portion. In such an embodiment, the image of the display panel 100 may be visible even on the curved portion.

The non-display area NDA may be defined as an area from the outside of the display area DA to the edge of the display panel 100. A scan driving portion for applying scan signals to scan lines and link lines connecting data lines and the display driving circuit 200 may be disposed in the non-display area NDA.

The protruding area PA may protrude from one side of the main area MA. In an embodiment, for example, the protruding area PA may protrude from a lower side of the main area MA as shown in FIG. 2. A length of the protruding area PA in the first direction (X-axis direction) may be smaller than a length of the main area MA in the first direction (X-axis direction).

The protruding area PA may include a bending area BA and a pad area PDA. In an embodiment, the pad area PDA may be disposed on one side of the bending area BA, and the main area MA may be disposed on the other side of the bending area BA. In an embodiment, for example, the pad area PDA may be disposed on a lower side of the bending area BA, and the main area MA may be disposed on an upper side of the bending area BA.

In an embodiment, the display panel 100 may be flexibly formed to be bent, warped, curved, folded, or curled. Therefore, the display panel 100 may be bent in the third direction or the thickness direction (Z-axis direction) in the bending area BA. In such an embodiment, before the display panel 100 is bent, one side of the pad area PDA of the display panel 100 is facing upward, but after the display panel 100 is bent, one side of the pad area PDA of the display panel 100 is facing downward. In such an embodiment, the pad area PDA is disposed on the lower part of the main area MA and may overlap the main area MA in the third direction (Z-axis direction).

Pads electrically connected to the display driving circuit 200 and the circuit board 300 may be disposed in the pad area PDA of the display panel 100.

The display driving circuit 200 outputs signals and voltages for driving the display panel 100. In an embodiment, for example, the display driving circuit 200 may supply data voltages to data lines. In an embodiment, the display driving circuit 200 may supply power voltage to the power supply line and may supply scan control signals to the scan driving portion. The display driving circuit 200 may be formed as an integrated circuit (IC) and mounted on the display panel 100 in the pad area PDA using a chip on glass (COG) method, a chip on plastic (COP) method, or an ultrasonic bonding method but is not limited to this. In an embodiment, for example, the display driving circuit 200 may be mounted on the circuit board 300.

The pads may include display pads electrically connected to the display driving circuit 200 and touch pads electrically connected to touch lines.

In an embodiment, the circuit board 300 may be attached to the pads using an anisotropic conductive film. In such an embodiment, the lead lines of the circuit board 300 may be electrically connected to the pads. The circuit board 300 may be a flexible film, such as a flexible printed circuit board, a printed circuit board, or a chip on film.

The touch driving circuit 400 may be connected to touch electrodes of the touch sensor layer TSL of the display panel 100. The touch driving circuit 400 applies driving signals to the touch electrodes of the touch sensor layer TSL and measures capacitance values of the touch electrodes. The driving signal may be a signal having a plurality of driving pulses. The touch driving circuit 400 may not only determine whether a touch is input based on capacitance values, but also calculate touch coordinates where a touch is input.

The touch driving circuit 400 may be disposed on the circuit board 300. The touch driving circuit 400 may be formed as an integrated circuit (IC) and mounted on the circuit board 300.

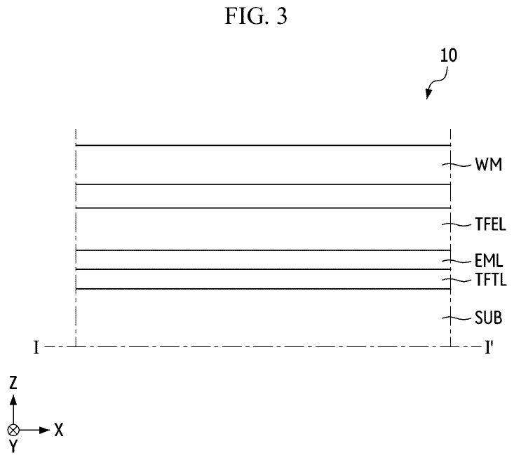

FIG. 3 is a cross-sectional view illustrating a portion of a cross-section taken along line I-I′ of FIG. 2.

Referring to FIG. 3, an embodiment of the display panel 100 may include a substrate SUB, and further include a thin film transistor layer TFTL, a light emitting element layer EML, and a thin film encapsulation layer TFEL, which are disposed on the substrate SUB. In an embodiment, the display panel 100 may further include a window member WM disposed on the thin film encapsulation layer TFEL.

The substrate SUB may include or be made of an insulating material such as glass, quartz, or polymer resin. Examples of polymeric materials include polyethersulphone (PES), polyacrylate (PA), polyarylate (PAR), polyetherimide (PEI), polyethylene napthalate (PEN), polyethylene terephthalate (PET), polyphenylene sulfonate (PS), polypropylene sulfonate (PS), polypropylene terephthalate (PET), polyphenylene sulfide (PPS), polyallylate, polyimide (PI), polycarbonate (PC), cellulose triacetate (CAT), cellulose acetate propionate (CAP), or combinations thereof. Alternatively, the substrate SUB may include a metal material.

The substrate SUB may be a rigid substrate or a flexible substrate capable of bending, folding, rolling, etc. In an embodiment where the substrate SUB is a flexible substrate, it may be formed of polyimide (PI) but is not limited thereto.

The thin film transistor layer TFTL may be disposed on the substrate SUB. In the thin film transistor layer TFTL, not only thin film transistors of each pixel, but also scan lines, data lines, power supply lines, scan control lines, and routing lines connecting pads and data lines may be formed. Each of the thin film transistors may include a gate electrode, a semiconductor layer, a source electrode, and a drain electrode.

The thin film transistor layer TFTL may be disposed in the display area DA and the non-display area NDA. In an embodiment, thin film transistors, scan lines, data lines, and power supply lines of each pixel of the thin film transistor layer TFTL may be disposed in the display area DA. The scan control lines and link lines of the thin film transistor layer TFTL may be disposed in the non-display area NDA.

The light emitting element layer EML may be disposed on the thin film transistor layer TFTL. The light emitting element layer EML may include pixels including a first electrode, a light emitting layer, and a second electrode, and a pixel defining layer defining the pixels. In an embodiment, the light emitting layer may be an organic light emitting layer including or containing an organic material. In such an embodiment, the light emitting layer may include a hole transporting layer, an organic light emitting layer, and an electron transporting layer. When a predetermined voltage is applied to the first electrode through a thin film transistor of the thin film transistor layer TFTL and a cathode voltage is applied to the second electrode, holes and electrons are moved to the organic light emitting layer through the hole transport layer and electron transport layer, respectively, and are combined with each other in the light emitting layer and emit light. The pixels of the light emitting element layer EML may be disposed in the display area DA.

The thin film encapsulation layer TFEL may be disposed on the light emitting element layer EML. In an embodiment, the thin film encapsulation layer TFEL serves to prevent oxygen or moisture from penetrating into the light emitting element layer EML. In such an embodiment, the thin film encapsulation layer TFEL may include at least one inorganic film. The inorganic film may include a silicon nitride layer, a silicon oxynitride layer, a silicon oxide layer, a titanium oxide layer, or an aluminum oxide layer but is not limited thereto. In an embodiment, the thin film encapsulation layer TFEL serves to protect the light emitting element layer EML from debris such as dust. In such an embodiment, the thin film encapsulation layer TFEL may include at least one organic layer. The organic film may include an acryl resin, an epoxy resin, a phenolic resin, a polyamide resin, or a polyimide resin but is not limited thereto.

The thin film encapsulation layer TFEL may be disposed in both the display area DA and the non-display area NDA. In an embodiment, the thin film encapsulation layer TFEL may be disposed to cover the light emitting element layer EML in the display area DA and the non-display area NDA and may be disposed to cover the thin film transistor layer TFTL in the non-display area NDA.

The window member WM may be disposed on the thin film encapsulation layer TFEL and may be optically transparent. Accordingly, the image generated in the display panel DP may pass through the window member WM.

Additional structures may be further disposed between the window member WM and the thin film encapsulation layer TFEL. In an embodiment, for example, a color filter layer, a touch sensing layer, or a micro lens array layer may be additionally disposed. The micro lens array layer may include a plurality of pixels and a plurality of micro lenses each corresponding to a plurality of pixels. Each of the plurality of micro lenses has a predetermined radius of curvature, magnifies the image output from the display panel DP, and then projects the magnified image on a virtual plane (not shown).

In an embodiment, a transparent adhesive member such as an optically clear adhesive (OCA) film may be further disposed between the window member WM and the lower layer.

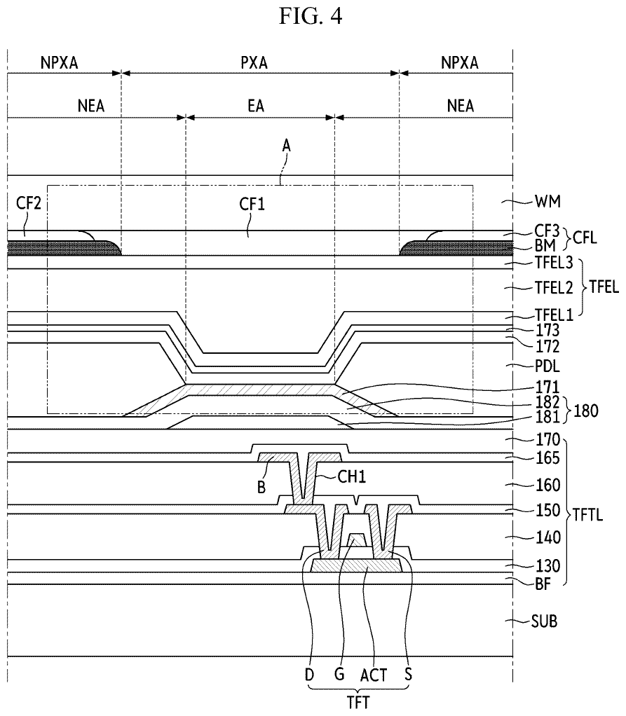

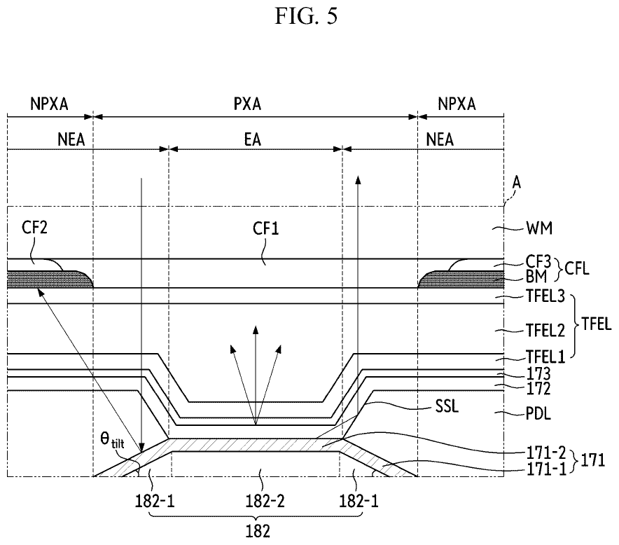

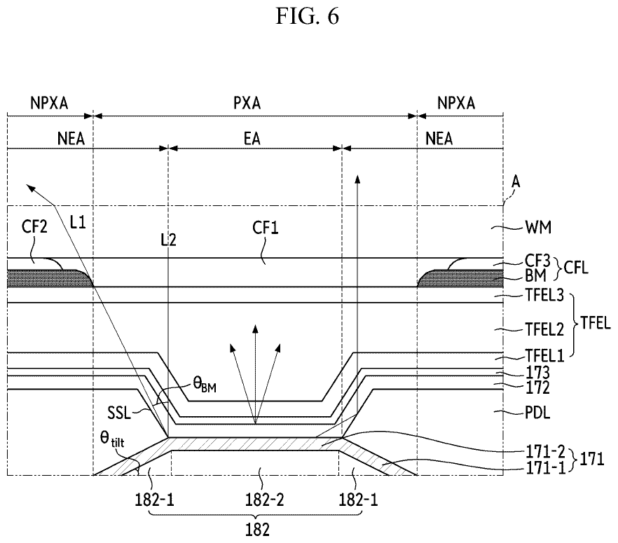

FIG. 4 is a cross-sectional view illustrating an example of a structure of a sub-pixel included in a display device according to an embodiment of the disclosure. FIGS. 5 and 6 are enlarged views of area A of FIG. 4. FIG. 5 is a view to illustrate the effect of reducing external light reflection due to the inclined structure (a structure or portion having an inclined surface with respect to the substrate SUB) of the first electrode 171, and FIG. 6 is a view to illustrate the relationship between the inclination angle of the first electrode 171 and the position of the light blocking pattern BM.

In an embodiment, a pixel may include a plurality of light emitting elements LEL and may be defined as the minimum or unit light emitting unit capable of displaying white light by combining light emitted by a plurality of light emitting elements LEL.

In an embodiment, a pixel may include a plurality of sub-pixels. Each of the plurality of sub-pixels may display light of different wavelengths.

Each of the sub-pixels represents an area where a first electrode 171, an organic light emitting layer 172, and a second electrode 173 that are sequentially stacked so that holes from the first electrode 171 and electrons from the second electrode 173 are combined with each other in the organic light emitting layer 172 to emit light. Each sub-pixel may include a light emitting element LEL.

The first electrode 171 may function as an anode electrode, and the second electrode 173 may function as a cathode electrode. However, it is not limited to this, and the polarities of the first electrode 171 and the second electrode 173 may be opposite to each other.

Hereinafter, referring to FIGS. 4 and 5, a thin film transistor layer TFTL is disposed or formed on the substrate SUB of the display device 10. The thin film transistor layer TFTL includes a buffer layer BF, a thin film transistors TFT, a gate insulating layer 130, an interlayer insulating layer 140, a first protective layer 150, a first planarization layer 160, a second protective layer 165, and a second planarization layer 170. The second planarization layer 170 may also be referred to as an insulating layer.

The substrate SUB may include or be made of an insulating material such as glass, quartz, or polymer resin. Examples of polymeric materials include polyethersulphone (PES), polyacrylate (PA), polyarylate (PAR), polyetherimide (PEI), polyethylene napthalate (PEN), polyethylene terephthalate (PET), polyphenylene sulfonate (PS), polypropylene sulfonate (PS), polypropylene terephthalate (PET), polyphenylene sulfide (PPS), polyallylate, polyimide (PI), polycarbonate (PC), cellulose triacetate (CAT), cellulose acetate propionate (CAP), or combinations thereof. Alternatively, the substrate SUB may include a metal material.

The substrate SUB may be a rigid substrate or a flexible substrate capable of bending, folding, rolling, etc. In an embodiment where the substrate SUB is a flexible substrate, it may be formed of polyimide (PI) but is not limited thereto.

The substrate SUB may include a light emitting area EA and a non-emitting area NEA defined by a pixel defining layer PDL, which will be described later.

In addition, the substrate SUB may include a light emitting area EA and a non-light emitting area NPXA defined by the light blocking pattern BM disposed on a color filter layer CFL.

The buffer layer BF may be disposed or formed on one surface of the substrate SUB. The buffer layer BF may be formed on one side of the substrate SUB to protect the thin film transistors TFT and the organic light emitting layer 172 of the light emitting element layer EML from moisture penetrating through the substrate SUB, which is vulnerable to moisture permeation. The buffer layer BF may be composed of or defined by a plurality of inorganic films alternately stacked. In an embodiment, for example, the buffer layer BF may be formed as a multilayer of alternately stacked inorganic films formed of at least two selected from a silicon nitride layer, a silicon oxynitride layer, a silicon oxide layer, a titanium oxide layer, and an aluminum oxide layer. In another embodiment, the buffer layer BF may be omitted.

The thin film transistor TFT is disposed or formed on the buffer layer BF. The thin film transistor TFT includes an active layer ACT, a gate electrode G, a source electrode S, and a drain electrode D. In an embodiment, as shown in FIG. 4, the thin film transistor TFT may have a top gate configuration in which the gate electrode G is located on top of the active layer ACT, but it is not limited thereto. In another embodiment, thin film transistors TFT may be formed in a bottom gate manner where the gate electrode G is located at the bottom of the active layer ACT or in a double gate manner where the gate electrode G is located at both the top and bottom of the active layer ACT.

The active layer ACT is disposed or formed on the buffer layer BF. The active layer ACT may include polycrystalline silicon, monocrystalline silicon, low temperature polycrystalline silicon, amorphous silicon, or an oxide semiconductor. For example, the oxide semiconductor may include a binary compound (ABx), a ternary compound (ABxCy), or a quaternary compound (ABxCyDz) containing indium, zinc, gallium, tin, titanium, aluminum, hafnium (Hf), zirconium (Zr), magnesium (Mg), or the like. For example, the active layer ACT may include an oxide comprising indium, tin, and titanium (ITZO) or an oxide comprising indium, gallium, and tin (IGZO). A light blocking layer may be disposed or formed between the buffer layer and the active layer ACT to block external light incident on the active layer ACT.

The gate insulating layer 130 may be disposed or formed on the active layer ACT. The gate insulating layer 130 may include or be formed of an inorganic film, such as a silicon nitride layer, a silicon oxynitride layer, a silicon oxide layer, a titanium oxide layer, or an aluminum oxide layer.

The gate electrode G and gate line may be disposed or formed on the gate insulating layer 130. The gate electrode G and the gate line may be formed as a single layer or multiple layers, each layer therein including at least one selected from molybdenum (Mo), aluminum (Al), chromium (Cr), gold (Au), titanium (Ti), nickel (Ni), neodymium (Nd), and copper (Cu), or an alloy thereof.

The interlayer insulating layer 140 may be disposed or formed on the gate electrode G and the gate line. The interlayer insulating layer 140 may include or be formed of an inorganic film, such as a silicon nitride layer, a silicon oxynitride layer, a silicon oxide layer, a titanium oxide layer, or an aluminum oxide layer.

The source electrode S and the drain electrode D may be disposed or formed on the interlayer insulating layer 140. Each of the source electrode S and the drain electrode D may be connected to the active layer ACT through a contact hole defined or formed through the gate insulating layer 130 and the interlayer insulating layer 140. The source electrode S and drain electrode D may be formed as a single layer or multiple layers, each layer therein including at least one selected from molybdenum (Mo), aluminum (Al), chromium (Cr), gold (Au), titanium (Ti), nickel (Ni), neodymium (Nd), and copper (Cu), or an alloy thereof.

The first protective layer 150 may be disposed or formed on the source electrode S and the drain electrode D to insulate the thin film transistor TFT. The first protective layer 150 may include or be formed of an inorganic film, such as a silicon nitride layer, a silicon oxynitride layer, a silicon oxide layer, a titanium oxide layer, or an aluminum oxide layer.

The first planarization layer 160 may be disposed or formed on the first protective layer 150 to flatten the step caused by the thin film transistor TFT.

The first planarization layer 160 may include or be formed of an organic film such as an acrylic resin, an epoxy resin, a phenolic resin, a polyamide resin, a polyimide resin, or the like.

A connection electrode B may be disposed or formed on the first planarization layer 160. The connection electrode B may be connected to the drain electrode D of the thin film transistor TFT through the first contact hole CH1 defined or formed through the planarization layer 160 and the first protective layer 150. The connection electrode B may be formed as a single layer or multiple layers, each layer therein including at least one selected from molybdenum (Mo), aluminum (Al), chromium (Cr), gold (Au), titanium (Ti), nickel (Ni), neodymium (Nd), and copper (Cu), or an alloy thereof.

The second protective layer 165 may be disposed or formed on the connection electrode B to insulate the thin film transistor TFT. The second protective layer 165 may include or be formed of an inorganic film, such as a silicon nitride layer, a silicon oxynitride layer, a silicon oxide layer, a titanium oxide layer, or an aluminum oxide layer. In another embodiment, at least one selected from the first protective layer 150 and the second protective layer 165 may be omitted.

The light emitting element layer EML may be disposed on the transistor layer TFTL. The light emitting element layer EML may include a via layer 180 having an inclined structure, light emitting elements LEL, and a pixel defining layer PDL.

The via layer 180 is disposed on the second planarization layer 170 and may have an inclined structure in the light exit area PXA.

The via layer 180 may include a first via layer 181 and a second via layer 182.

The first via layer 181 may be disposed in the light exit area PXA of each sub-pixel. The first via layer 181 may be convex upward in the light exit area PXA and may have a lens shape with a relatively gentle or flat top surface.

The first via layer 181 may be island-shaped in a plan view or when viewed in a thickness direction of the substrate SUB. The top surface of the first via layer 181 may be substantially parallel to the top surface of the substrate SUB. In this specification, “in a plane” is set based on a plane parallel to the plane defined by the first direction DR1 and the second direction DR2.

The second via layer 182 may be disposed or formed on the entire surface of the second planarization layer 170 to cover the first via layer 181. The second via layer 182 may have an inclined structure in the light exit area PXA by overlapping with the first via layer 181.

The inclined structure of the second via layer 182 may include a first portion 182-1 having a tilt angle (also referred to as “inclination angle”) θₜᵢₗₜ and a second portion 182-2 extending from the top of the first portion 182-1. The tilt angle θₜᵢₗₜ is an angle of a surface of the inclined structure of the second via layer 182 formed with a top surface of the substrate SUB. The tilt angle θₜᵢₗₜ may be in a range of about 10° to about 30°. In an embodiment, for example, the tilt angle θₜᵢₗₜ may be in a range of about 15° to about 30°.

As the inclined structure includes the first portion 182-1 having a tilt angle θₜᵢₗₜ, the inclined structure may have an upper width (a width of an upper or top surface) that is substantially narrower than the lower width (a width of a lower or bottom surface).

Due to the inclined structure of the via layer 180, some of the light incident from the outside may be reflected toward the light blocking pattern BM.

In an embodiment, the first via layer 181 and the second via layer 182 may include or be formed of a same or similar organic material as each other. In another embodiment, the first via layer 181 and the second via layer 182 may include or be formed of different organic materials.

In an embodiment, each of the light emitting elements LEL may include a first electrode 171, an organic light emitting layer 172, and a second electrode 173.

The first electrode 171 is disposed on the via layer 180 having an inclined structure. As the first electrode 171 is disposed on the inclined structure of the via layer 180, the first electrode 171 may also have an inclined structure. The first electrode 171 may have an upwardly convex shape.

In an embodiment, for example, the first electrode 171 may include an inclined portion 171-1 disposed on a first portion 182-1 of the second via layer 182 and having a tilt angle θₜᵢₗₜ, and a top end portion 171-2 disposed on the second portion 182-2 of the second via layer 182. The tilt angle θₜᵢₗₜ is an angle of the first electrode 171 formed with a plane parallel to a top surface of the substrate SUB. The tilt angle θₜᵢₗₜ may be in a range of about 10° to about 30°. In an embodiment, for example, the tilt angle θₜᵢₗₜ may be in a range of about 15° to about 30°.

The top end portion 171-2 may also be referred to as an extension portion that extends from the inclined portion 171-1.

The inclined portion 171-1 may overlap the pixel defining layer PDL, which will be described later, and may extend toward the outside inclined downwardly toward the substrate SUB due to the inclined structure.

The top end portion 171-2 extends from the upper end of the inclined portion 171-1 and does not vertically overlap the inclined portion 171-1. In a plan view, the inclined portion 171-1 may have a shape surrounding the top end portion 171-2. The top end portion 171-2 may be flat but may be formed to have a curvature during the process. In such an embodiment, the top end portion 171-2 may be formed to be relatively flat or planar compared to the inclined portion 171-1.

In an embodiment, as shown in FIG. 5, when external light is incident on the inclined portion 171-1 of the first electrode 171, the incident light may be reflected by the inclined portion 171-1 towards the light blocking pattern BM on top. In such an embodiment, the tilt angle θₜᵢₗₜ of the inclined portion 171-1 may be determined based on the position of the light blocking pattern BM.

Referring to FIG. 6, in an embodiment, the tilt angle θₜᵢₗₜ is determined in a way such that the tilt angle θₜᵢₗₜ is greater than half an angle θ_{BM} formed between a first imaginary line L1 extending from a first side of the pixel-defining layer PDL to a first side of the light blocking pattern BM adjacent to the first side of the pixel-defining layer PDL and a second imaginary vertical line L2 of the substrate (SUB in FIG. 4) from the first side of the pixel-defining layer PDL, i.e., θₜᵢₗₜ≥θ_{BM}/2 is satisfied. One end of the pixel defining layer PDL is on the boundary where the organic light emitting layer 172 and the pixel defining layer PDL meet in a plan view. In such an embodiment, the tilt angle θₜᵢₗₜ satisfies the condition θₜᵢₗₜ≥θ_{BM}/2, such that the external light reflectance may be effectively reduced.

The pixel defining layer PDL may be disposed on the via layer 180 and the first electrode 171. The pixel defining layer PDL may be formed to compartmentalize or partition the light emitting area EA and the non-emitting area NEA. The pixel defining layer PDL may be formed to cover the edge portion (or the inclined portion 171-1) of the first electrode 171.

In an embodiment, the pixel defining layer PDL may define or be provided with an opening PDL-O that exposes the top end 171-2 of the first electrode 171. The pixel defining layer PDL may cover the inclined portion 171-1 of the first electrode 171.

The pixel defining layer PDL may be formed from a transparent organic film, such as an acrylic resin, an epoxy resin, a phenolic resin, a polyamide resin, a polyimide resin, or the like.

The pixel defining layer PDL may have a lower refractive index than other organic layers. In an embodiment, for example, the pixel defining layer PDL may have a lower refractive index than the via layer 180. Since the pixel defining layer PDL has a low refractive index, light emitted from the organic light emitting layer 172 may be effectively reflected to the light exit area PXA.

The organic light emitting layer 172 may be disposed on the first electrode 171 and the pixel defining layer PDL.

The organic light emitting layer 172 may be disposed in contact with the top end portion 171-2 of the first electrode 171 and may extend along a slope (or inclined side) surface SSL of the pixel defining layer PDL.

Accordingly, the organic light emitting layer 172 may also have an inclined portion that overlaps the inclined portion 171-1 of the first electrode 171 and a bottom portion that overlaps the top end portion 171-2 of the first electrode 171. The organic light emitting layer 172 may extend from the inclined portion to the pixel defining layer PDL.

In an embodiment, the organic light emitting layer 172 may emit one of red light, green light, and blue light. The wavelength of red light may be in a range about 620 nanometers (nm) to about 750 nm, and the wavelength of green light may be in a range of about 495 nm to about 570 nm. Additionally, the wavelength of blue light may be in a range of about 450 nm to about 495 nm.

In another embodiment, for example, the organic light emitting layer 172 may emit white light. In such an embodiment where the organic light emitting layer 172 emits white light, the organic light emitting layer 172 may have a stacked structure including a red light emitting layer, a green light emitting layer, and a blue light emitting layer. Additionally, a separate color filter may be further included for displaying red, green, and blue.

Although not shown in the drawing, the organic light emitting layer 172 may have a multilayer structure including a hole transporting layer, an organic light emitting layer, and an electron transporting layer.

The second electrode 173 is disposed or formed on the organic light emitting layer 172 and the pixel defining layer PDL. The second electrode 173 may be formed to cover the organic light emitting layer 172 and the pixel defining layer PDL. The second electrode 173 may be a common layer commonly formed over all light emitting elements LEL. In an embodiment, the second electrode 173 may be a cathode electrode. In an embodiment, the second electrode 173 is made of Li. The second electrode 173 may include at least one selected from Li. Ca, Lif/Ca, LiF/Al, Al, Ag, and Mg in an embodiment. Additionally, the second electrode 173 may be a transparent or translucent electrode including at least one selected from indium tin oxide (ITO), indium zinc oxide (IZO), zinc oxide (ZnO), indium oxide (In₂O₃), indium gallium oxide (IGO), and aluminum zinc oxide (AZO) in an embodiment.

In the upper light emitting structure, the second electrode 173 may be formed of a transparent conductive oxide (TCO), such as indium tin oxide (ITO) and indium zinc oxide (IZO), which may transmit light, or a semi-transmissive conductive material, such as magnesium (Mg), silver (Ag), or an alloy of magnesium (Mg) and silver (Ag). In an embodiment where the second electrode 173 includes or is made of a translucent metal material, light output efficiency may be increased due to a micro cavity effect.

An encapsulation layer TFEL may be disposed on the second electrode 173. The encapsulation layer TFEL is disposed on the second electrode 173. The encapsulation layer TFEL may include at least one inorganic film to prevent oxygen or moisture from penetrating into the organic light emitting layer 172 and the second electrode 173. Additionally, the encapsulation layer TFEL may include at least one organic film to protect the light emitting element layer EML from debris such as dust. In an embodiment, for example, the encapsulation layer TFEL may include a first inorganic layer TFE1 disposed on the second electrode 173, an organic film TFE2 disposed on the first inorganic film TFE1, and a second inorganic film TFE3 disposed on the organic film TFE2. The first inorganic film TFE1 and the second inorganic film TFE3 may include or be formed of a silicon nitride layer, a silicon oxynitride layer, a silicon oxide layer, a titanium oxide layer, or an aluminum oxide layer but are not limited thereto. The organic film may include or be formed of, but is not limited to, an acrylic resin, an epoxy resin, a phenolic resin, a polyamide resin, a polyimide resin, or the like.

A second buffer layer may be disposed or formed on the thin film encapsulation layer TFEL. The second buffer layer may be composed of a plurality of inorganic films stacked alternately one on another. In an embodiment, for example, the second buffer layer may be formed as a multilayer of alternately stacked inorganic films of at least two selected from a silicon nitride layer, a silicon oxynitride layer, a silicon oxide layer, a titanium oxide layer, and an aluminum oxide layer. In another embodiment, the second buffer layer may be omitted.

The color filter layer CFL may be disposed on the thin film encapsulation layer TFEL.

The color filter layer CFL may include a light blocking pattern BM and at least one color filter CF1, CF2, and CF3.

The light blocking pattern BM is disposed in the non-light area NPA, and the material constituting the light blocking pattern BM is not particularly limited as long as it is a material that absorbs light. The light blocking pattern BM is a layer having a black color, and in an embodiment, the light blocking pattern BM may include a black coloring agent. The black ingredients may include black dye and black pigment. The black component may include metals such as carbon black and chromium, or oxides thereof.

The light blocking pattern BM may absorb external light reflected by the inclined portion 171-1 of the first electrode 171.

The color filters CF1, CF2, and CF3 may overlap the light output area PA. The color filter CF may partially overlap or contact the light blocking pattern BM.

The color filters CF1, CF2, and CF3 transmit light in a specific wavelength range and block light outside that wavelength range. In an embodiment, for example, the first color filter CF1 in the first light emitting area may transmit light of the first wavelength and block light of other wavelengths.

The color filters CF1, CF2, and CF3 include a base resin and dye and/or pigment dispersed in the base resin. The base resin is a medium in which dyes and/or pigments are dispersed, and may be made of various resin compositions, which may generally be referred to as binders. The color filters CF1, CF2, and CF3 may have a uniform thickness within the light exit area PXA. Accordingly, light emitted from the organic light emitting layer 172 may be provided to the outside with uniform luminance within the light exit area PXA.

A window member WM may be disposed on the color filter layer CFL. An overcoating layer may be further disposed between the color filter layer CFL and the window member WM. The overcoating layer may flatten the color filter layer CFL. The overcoating layer may include organic material.

The window member WM may have a multi-layer structure. The window member WM includes at least one base layer. The base layer may be a glass substrate or a synthetic resin film. The window member WM may include a thin glass substrate and a synthetic resin film disposed on the thin glass substrate. The thin glass substrate and the synthetic resin film may be bonded by an adhesive layer, and the adhesive layer and the synthetic resin film may be separated from the thin glass substrate for their replacement thereof.

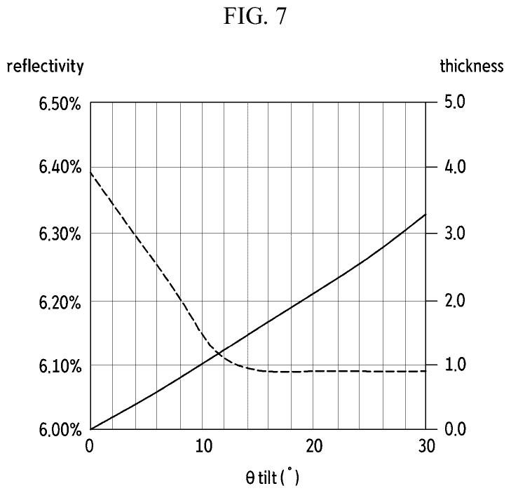

FIG. 7 is a graph illustrating the relationship between the reflectance and the inclination angle and the thickness of the through layer and the inclination angle according to an embodiment. FIG. 7 illustrates result values applied to the display device described with reference to FIGS. 4 to 6. The thickness of the via layer in FIG. 7 is the thickness of the second via layer 182 described with reference to FIGS. 4 to 6. Additionally, the inclination angle in FIG. 7 is the tilt angle θₜᵢₗₜ of the second via layer 182 described with reference to FIGS. 4 to 6.

Referring to the dotted line in FIG. 7, when the inclination angle is about 15° or more, the reflectance is reduced by about 0.3%. Referring to the solid line in FIG. 7, the inclination angle increases almost proportionally as the thickness of the via layer becomes thicker. However, it is difficult to implement a thickness of the via layer greater than about 3 micrometers (μm) due to process limitations.

Therefore, in terms of reducing external light reflectance, the thickness of the via layer may be in a range about 1.5 μm to about 3 μm, and the inclination angle may be in the range of about 15° to about 30°. In an embodiment, for example, the tilt angle θₜᵢₗₜ may be in a range about 15° to about 30°.

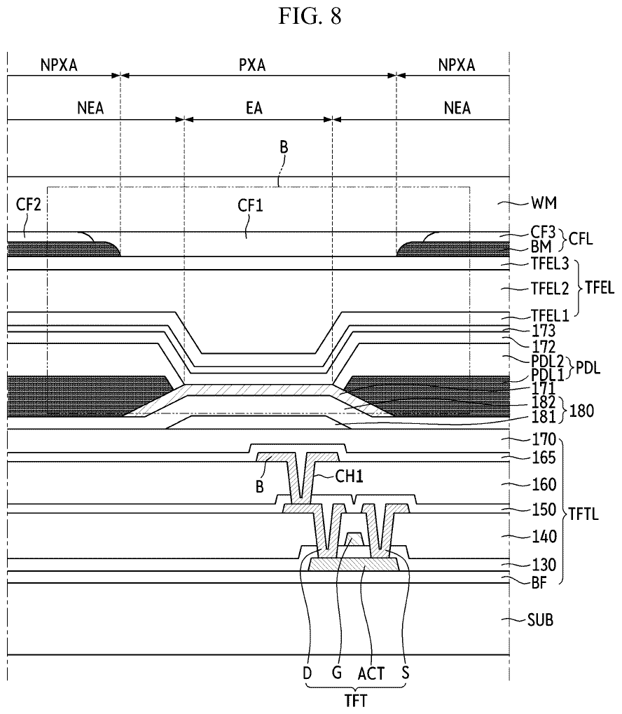

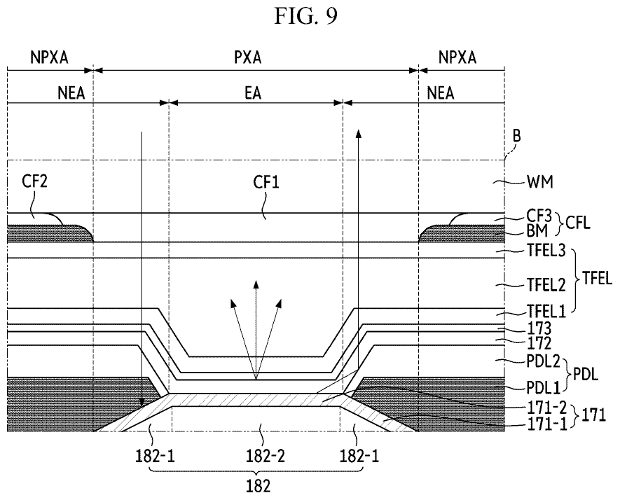

FIG. 8 is a cross-sectional view illustrating an example of a structure of a sub-pixel included in a display device according to an embodiment of the disclosure. FIG. 9 is an enlarged view of area B of FIG. 8.

The embodiment of FIGS. 8 and 9 is substantially the same as the embodiment described with reference to FIGS. 4 to 7 except that the pixel defining layer PDL is formed of multiple layers. In description of the embodiments of FIGS. 8 and 9, any repetitive detailed descriptions of the same or like elements as those of the embodiment of FIG. 5 will be omitted or simplified.

Referring to FIGS. 8 and 9, in an embodiment, a pixel defining layer PDL may include a first pixel defining layer PDL1 and a second pixel defining layer PDL2.

The first pixel defining layer PDL1 is disposed on the inclined portion 171-1 of the first electrode 171 and the via layer 180. The first pixel defining layer PLD1 has a first thickness T1 and is disposed to cover most of the inclined portion 171-1 of the first electrode 171.

The first pixel defining layer PDL1 may overlap the non-emitting area NEA and may not overlap the light emitting area EA. Further, a portion of the first pixel defining layer PDL1 may overlap the light exit area PXA.

The first pixel defining layer PDL1 may include a black coloring agent. The black ingredients may include black dye and black pigment. The black component may include metals such as carbon black and chromium, or oxides thereof.

Accordingly, the first pixel defining layer PLD1 may absorb external light incident from the outside in the first pixel defining layer PDL1 overlapping the light exit area PXA.

The second pixel defining layer PDL2 is disposed on the first pixel defining layer PDL1 and may completely cover the first pixel defining layer PDL1 in a plan view. Accordingly, the first pixel defining layer PDL1 is not in contact with the organic light emitting layer 172.

The second pixel defining layer PDL2 may include or be formed of a transparent organic film such as an acrylic resin, an epoxy resin, a phenolic resin, a polyamide resin, a polyimide resin, or the like.

The second pixel defining layer PDL2 may have a lower refractive index than other organic layers. In an embodiment, for example, the pixel defining layer PDL may have a lower refractive index than the first pixel defining layer PLD1.

The sloped surface SSL2 of the second pixel defining layer PDL2 may be in contact with the organic light emitting layer 172.

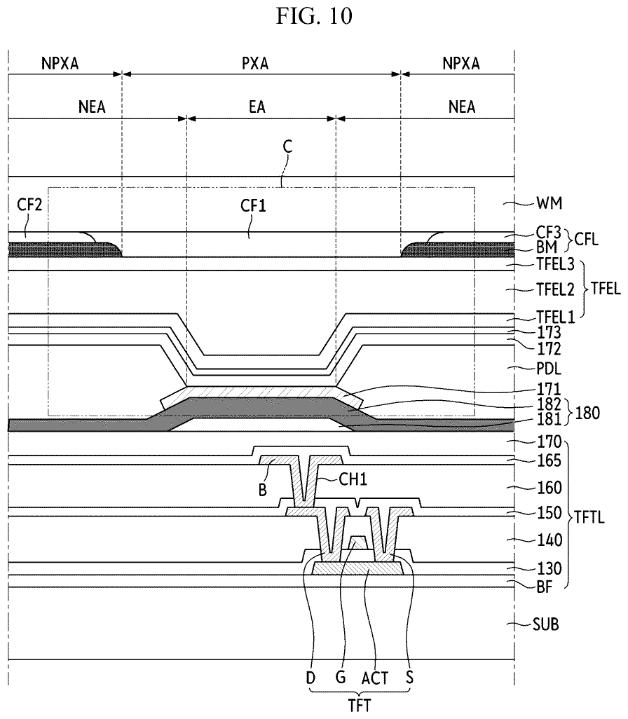

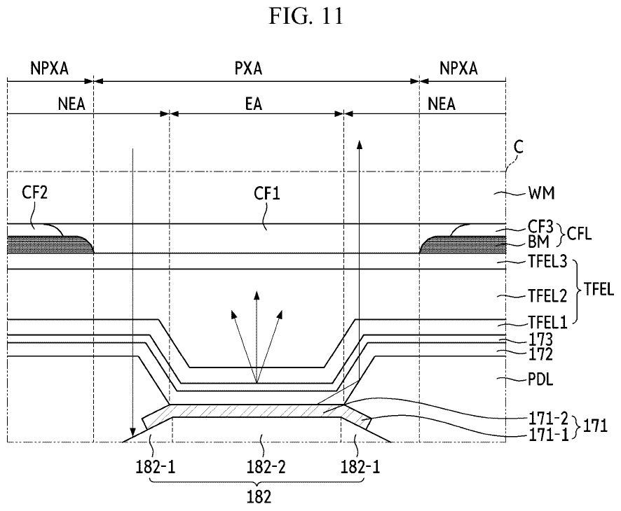

FIG. 10 is a cross-sectional view illustrating an example of a structure of a sub-pixel included in a display device according to an embodiment of the disclosure. FIG. 11 is an enlarged view of area C of FIG. 10.

The embodiment of FIGS. 10 and 11 is substantially the same as the embodiment described with reference to FIGS. 4 to 7 except that the second via layer 182 includes a black component. In description of the embodiments of FIGS. 10 and 11, any repetitive detailed descriptions of the same or like elements as those of the embodiments of FIGS. 4 to 7 will be omitted or simplified.

Referring to FIGS. 10 and 11, in an embodiment, the second via layer 182 includes a black component, and the black component may include black dye and black pigment. The black component may include metals such as carbon black and chromium, or oxides thereof.

The second via layer 182 may have an inclined structure in the light exit area PXA.

The inclined structure of the second via layer 182 may include a first portion 182-1 having a tilt angle θₜᵢₗₜ and a second portion 182-2 extending from the top of the first portion 182-1. The tilt angle θₜᵢₗₜ is an angle of the first portion 182-1 formed with the top surface of the substrate SUB. The tilt angle θₜᵢₗₜ may be in a range about 10° to about 30°. In an embodiment, for example, the tilt angle θₜᵢₗₜ may be in a range of about 15° to about 30°.

As the inclined structure includes the first portion 182-1 having a tilt angle θₜᵢₗₜ, the inclined structure may have an upper width that is substantially narrower than the lower width.

A first electrode 171 is disposed on the second via layer 182. The first electrode 171 may include an inclined portion 171-1 disposed on the first portion 182-1 and a top portion 171-2 disposed on the second portion 182-2.

The first inclined portion 171-1 may be disposed only on a portion of the first portion 182-1. A portion of the first portion 182-1 may be exposed by the first inclined portion 171-1. In an embodiment, for example, the first portion 182-1 exposed by the first inclined portion 171-1 may be disposed in the non-emitting area NEA while being the light exit area PXA. The first portion 182-1 does not overlap the light blocking pattern BM. When external light is incident on the first portion 182-1 exposed by the first inclined portion 171-1, the external light may be absorbed to minimize reflection of the external light.

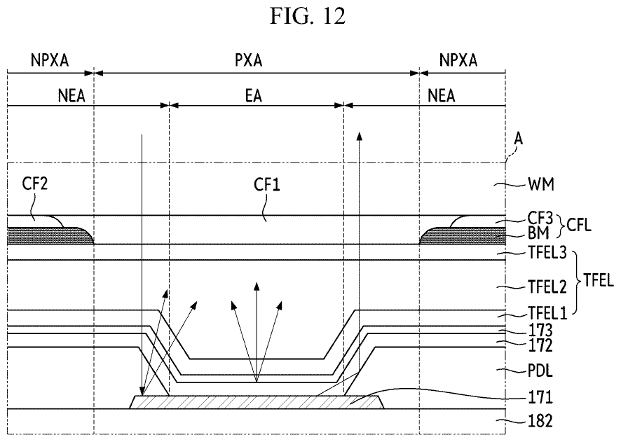

FIGS. 12 to 14 are cross-sectional view illustrating a structure of a sub-pixel corresponding to FIG. 5, according to other embodiments.

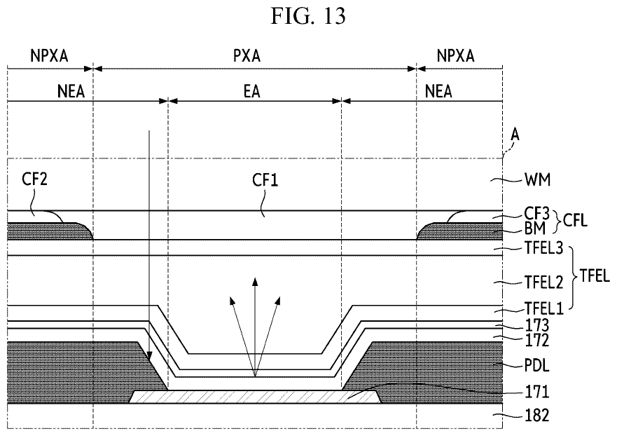

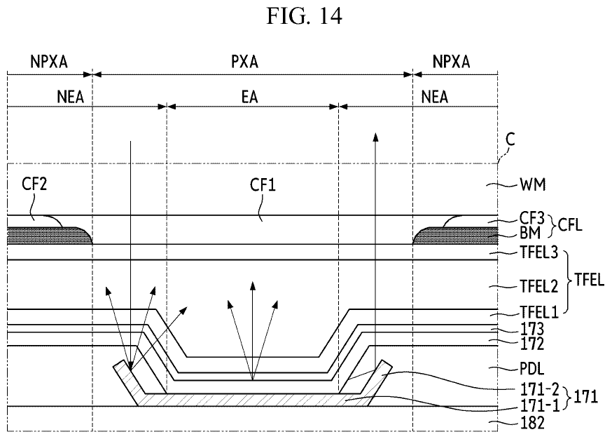

The embodiment of FIG. 12 is substantially the same as the embodiments described with reference to FIGS. 4 to 7 except that the via layer 180 and the first electrode 171 do not have an inclined structure. The embodiment of FIG. 13 is substantially the same as the embodiment described with reference to FIGS. 4 to 7 except that the pixel defining layer PDL includes a black component and the first electrode 171 does not have an inclined structure. FIG. 14 substantially the same as the embodiment described with reference to FIGS. 4 to 7 except that the first electrode 171 has a concave inclined structure below the first electrode 171. For convenience of description, the different configurations of the embodiments of FIGS. 12 to 14 from the embodiments of FIGS. 4 to 7 will hereinafter be mainly described.

Referring to FIG. 12, in an embodiment, the via layer 180 and the first electrode 171 have a straight or planar structure without an inclined structure.

The via layer 180 and the first electrode 171 may be disposed parallel to the lower structure of the substrate (SUB in FIG. 4).

The first electrode 171 may be disposed wider than the light emitting area EA. Accordingly, the first electrode 171 may be disposed to overlap the non-emitting area NEA. When external light is incident, the first electrode 171 overlapping the non-emitting area NEA may reflect the external light to the light emitting area. Accordingly, external light reflectance may increase.

Referring to FIG. 13, in another embodiment, the via layer 180 and the first electrode 171 have a straight or planar structure without an inclined structure. The via layer 180 and the first electrode 171 may be disposed parallel to the lower structure of the substrate (SUB in FIG. 4).

The first electrode 171 may be disposed wider than the light emitting area EA. Accordingly, the first electrode 171 may be disposed to overlap the non-emitting area NEA.

In such an embodiment, the pixel defining layer PDL may include a black component, and the black component may include black dye and black pigment. The black component may include metals such as carbon black and chromium, or oxides thereof.

Accordingly, since external light incident in the area overlapping the non-emitting area NEA is absorbed by the pixel defining layer PDL, the external light reflectance may be minimized. However, since the pixel defining layer PDL has the property of absorbing light, some of the light emitted from the organic light emitting layer 172 may be absorbed by the pixel defining layer PDL, thereby reducing light output efficiency.

Referring to FIG. 14, in another embodiment, the via layer 180 has a straight or planar structure without an inclined structure.

The first electrode 171 has an inclined structure and is disposed to be inclined upwardly toward the window member WM as it goes outward. The first electrode 171 has a downward concave structure.

When the external light is incident on the first electrode 171 overlapping the non-emitting area NEA, the first electrode 171 may reflect the external light into the emission area. Accordingly, the external light reflectance may increase.

As described above, in such an embodiment, the first electrode 171 has an inclined structure, and when the inclined portion of the first electrode 171 is inclined toward the substrate, the external light reflectance may be reduced even if the pixel defining layer PDL does not include a black component.

As a result, the effects of both improving the light output efficiency of the display device and reducing the external light reflectance may be achieved.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate;
a via layer disposed on the substrate and having an inclined structure;
a first electrode disposed on the inclined structure wherein the first electrode includes an inclined portion and an extension portion;
a pixel defining layer disposed on the via layer and the inclined portion of the first electrode, wherein an opening exposing an extension of the first electrode is defined through the pixel defining layer;
an organic light emitting layer disposed on the first electrode; and
a second electrode disposed on the organic light emitting layer,
wherein the extension portion extends from a top end of the inclined portion,
wherein the inclined portion corresponds to an edge portion of the first electrode, and a bottom end of the inclined portion is closer to the substrate than the top end thereof is.

2. The display device of claim 1, wherein the inclined portion has a surface forming a first inclination angle with respect to a plane parallel to the substrate, and the first inclination angle is in a range of about 10° to about 30°.

3. The display device of claim 1, wherein the inclined structure includes a first portion having a surface forming a second inclination angle with respect to a plane parallel to the substrate, and a second portion extending from a top end of the first portion.

4. The display device of claim 3, wherein the second inclination angle is in a range of about 10° to about 30°.

5. The display device of claim 3, wherein the inclined portion overlaps the first portion in a plan view, and the extension portion overlaps the second portion in the plan view.

6. The display device of claim 1, wherein an upper width of the inclined structure is less than a lower width thereof.

7. The display device of claim 1, wherein the via layer includes a first via layer disposed in an island-shape in an area overlapping the opening, and a second via layer covering the first via layer and disposed on an entire surface of the substrate.

8. The display device of claim 1, wherein the pixel defining layer includes a transparent organic material,
wherein the pixel defining layer has a lower refractive index than the via layer.

9. The display device of claim 1, wherein the pixel defining layer includes a first pixel defining layer including a black component, and a second pixel defining layer disposed on the first pixel defining layer,
wherein the second pixel defining layer includes a transparent organic material and has a lower refractive index than the first pixel defining layer.

10. The display device of claim 9, wherein the first pixel defining layer defines the opening,
wherein the second pixel defining layer is not in contact with the organic light emitting layer.

11. The display device of claim 9, wherein the black component includes at least one material selected from carbon black, chromium, and chromium oxide.

12. The display device of claim 3, wherein the via layer includes at least one material selected from carbon black, chromium, and chromium oxide.

13. The display device of claim 3, wherein the inclined portion overlaps the first portion and exposes at least a portion of the first portion.

14. The display device of claim 1, further comprising:
a thin film transistor disposed between the substrate and the via layer; and
a planarization layer disposed between the thin film transistor and the via layer,
wherein the first electrode is electrically connected to the thin film transistor.

15. A display device comprising:
a substrate;
a via layer disposed on the substrate and having an inclined structure;
a first electrode disposed on the inclined structure, wherein the first electrode includes an inclined portion and an extension portion;
a pixel defining layer disposed on the via layer and an inclined portion of the first electrode, wherein an opening exposing an extension of the first electrode is defined through the pixel defining layer;
an organic light emitting layer disposed on the first electrode;
a second electrode disposed on the organic light emitting layer;
an encapsulation layer disposed on the second electrode; and
a light blocking pattern disposed on the encapsulation layer,
wherein a surface of the inclined portion has a first inclination angle with respect to a plane parallel to the substrate,
wherein the first inclination angle is at least half of a third inclination angle formed between an imaginary line extending from one end of the pixel defining layer to one end of a light blocking pattern adjacent to the one end of the pixel defining layer and an imaginary vertical line of the substrate.

16. The display device of claim 15, wherein the extension portion extends from a top end of the inclined portion,
wherein the inclined portion corresponds to an edge portion of the first electrode, and a bottom end of the inclined portion is closer to the substrate than the top end thereof is.

17. The display device of claim 15, wherein the light blocking pattern includes at least one material selected from carbon black, chromium, and chromium oxide.

18. The display device of claim 15, wherein the first inclination angle is in a range of about 10° to about 30°.

19. The display device of claim 15, wherein the via layer includes a first via layer disposed in an island-shape in an area overlapping the opening, and a second via layer covering the first via layer and disposed on the entire surface of the substrate.

20. The display device of claim 15, further comprising:
a thin film transistor disposed between the substrate and the via layer; and
a planarization layer disposed between the thin film transistor and the via layer,
wherein the first electrode is electrically connected to the thin film transistor.
